(19) United States
(12) Patent Application Publication
(10) Pub. No.: US 2018/0212179 A1
(43) Pub. Date: Jul. 26, 2018

(54) OLED DISPLAY PANEL AND MANUFACTURE METHOD THEREOF

(71) Applicant: Wuhan China Star Optoelectronics Technology Co., Ltd., Wuhan City, Hubei (CN)

(72) Inventor: Wei YU, Wuhan City (CN)

(73) Assignee: Wuhan China Star Optoelectronics Technology Co., Ltd., Wuhan City, Hubei (CN)

(21) Appl. No.: 15/503,715

(22) PCT Filed: Dec. 29, 2016
(86) PCT No.: PCT/CN2016/113050

§ 371 Date: Feb. 14, 2017

(30) Foreign Application Priority Data
Dec. 22, 2016 (CN) 201611200142.8

(51) Int. Cl. H01L 51/50; H01L 51/52; H01L 51/56; H01L 51/00; H01L 27/32

(52) U.S. Cl. CPC H01L 51/5012; H01L 51/5056; H01L 51/5072; H01L 51/5092; H01L 51/5231; H01L 51/5234; H01L 51/56; H01L 51/0097; H01L 27/3262; H01L 51/5218

(57) ABSTRACT

The present invention provides an OLED display panel and a manufacture method thereof. In the manufacture method of the OLED display panel according to the present invention, the cathode of the made OLED display panel has a double layer structure. The cathode comprises a first metal layer of the entire surface and a second metal layer being located on the first metal layer and corresponding to the non pixel areas of the OLED display panel. Thus, in the pixel area of the OLED display panel, the cathode is constructed by the first metal layer and appears to be semi transparent. In the non pixel area of the OLED display panel, the cathode is constructed by stacking up the first metal layer, the second metal layer and appears to be opaque.

### FIELD OF THE INVENTION

The present invention relates to a display technology field, and more particularly to an OLED display panel and a manufacture method thereof.

### BACKGROUND OF THE INVENTION

The Organic Light Emitting Display (OLED) device possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device.

The OLED can be categorized into two major types according to the driving ways, which are the Passive Matrix OLED (PMOLED) and the Active Matrix OLED (AMOLED), i.e. two types of the direct addressing and the Thin Film Transistor matrix addressing. The AMOLED comprises pixels arranged in array and belongs to active display type, which has high lighting efficiency and is generally utilized for the large scale display devices of high resolution.

The OLED display element generally comprises a substrate, an anode located on the substrate, a Hole Injection Layer located on the anode, a Hole Transporting Layer located on the Hole Injection Layer, an emitting layer located on the Hole Transporting Layer, an Electron Transport Layer located on the emitting layer, an Electron Injection Layer located on the Electron Transport Layer and a Cathode located on the Electron Injection Layer. The principle of the OLED element is that the illumination generates due to the carrier injection and recombination under the electric field driving of the semiconductor material and the organic semiconductor illuminating material. Specifically, the Indium Tin Oxide (ITO) electrode and the metal electrode are respectively employed as the anode and the cathode of the Display. Under certain voltage driving, the Electron and the Hole are respectively injected into the Electron and Hole Transporting Layers from the cathode and the anode. The Electron and the Hole respectively migrate from the Electron and Hole Transporting Layers to the Emitting layer and bump into each other in the Emitting layer to form an exciton to excite the emitting molecule. The latter can illuminate after the radiative relaxation.

As shown in FIG. 1, in the OLED display panel according to prior art, for preventing the contrast decrease caused by the reflection of the outdoor light, a circular polarizer 100 is adhered on the light outgoing side of the OLED display panel in general, and the external light will change to be polarized light after passing through the circular polarizer 100, and then will become the polarized light perpendicular with the polarization direction of the circular polarizer 100 after being reflected by the reflection electrode of the thin film transistor 200 and then outgoing from the circular polarizer 100. Thus, it cannot enter the human eyes through the circular polarizer 100 to ensure the outdoor contrast of the OLED display panel to promote the display result. The reflection electrode of the thin film transistor 200 comprises: a gate, a source and a drain, a scan line coupled to the gate and a data line coupled to the source. However, the circular polarizer 100 cannot stop the light emitted by the OLED element 300 itself to decrease the contrast of the OLED display panel. As shown in FIG. 1, in the OLED display panel according to prior art, the light emitted by the OLED element 300 does not outgo at all as being perpendicular with the substrate 400. A portion of light will outgo from the lateral side of the OLED element 300. After being reflected by the reflection electrode of the thin film transistor 200 and incident into the circular polarizer 100 through the non aperture area 510 (corresponding to the non pixel area of the OLED display panel) of the pixel definition layer 500, the light is received by the human eyes through the circular polarizer 100. The contrast of the OLED display panel will be decreased and the display result is influenced.

### SUMMARY OF THE INVENTION

An objective of the present invention is to provide a manufacture method of an OLED display panel, which can effectively raise the contrast of the OLED display panel to promote the display result, and meanwhile can raise the conduction property of the cathode to decrease the power consumption of the OLED display panel.

Another objective of the present invention is to provide an OLED display panel, which has high contrast and great display result, and meanwhile, the conduction property of the cathode thereof is good and the power consumption is low.

For realizing the aforesaid objectives, the present invention provides a manufacture method of an OLED display panel, comprising steps of:

providing a substrate, and forming a thin film transistor layer on the substrate, and the thin film transistor layer comprising a plurality of thin film transistors separately located;

forming a planarization layer on the thin film transistor layer, and forming a plurality of through holes in the planarization layer respectively and correspondingly above the plurality of thin film transistors;

forming a plurality of anodes separately located on the planarization layer, and the plurality of anodes being coupled to the plurality of thin film transistors respectively through the plurality of through holes;

forming a pixel definition layer on the planarization layer, and the pixel definition layer comprising a plurality of aperture areas which respectively correspond to the plurality of anodes and non aperture areas among the plurality of aperture areas;

respectively forming a plurality of OLED light emitting layers located on the plurality of anodes in the plurality of aperture areas of the pixel definition layer;

forming a first metal layer covering the plurality of OLED light emitting layers and the pixel definition layer with an entire surface on the plurality of OLED light emitting layers and the pixel definition layer, and forming a second metal layer corresponding to the non aperture areas of the pixel definition layer on the first metal layer, and the first metal layer and the second metal forming a cathode together, and the first metal layer appearing to be semi transparent, and an overlapping area of the first metal layer and the second metal layer appearing to be opaque.

An evaporation process is employed to form the first metal layer and the second metal layer; a material of the first metal layer is magnesium silver alloy; a material of the second metal layer comprises at least one of magnesium, silver and aluminum.

A thickness of the first metal layer is 100 μm-200 μm; a thickness of the second metal layer is more than 100 μm.

Furthermore, the manufacture method of the OLED display panel according to the present invention further comprises:

forming a package layer on the cathode;

adhering a circular polarizer on the package layer.

The package layer is a thin film package layer, and the package layer comprises a plurality of inorganic layers and organic layers stacked up and alternately located.

The present invention further provides an OLED display panel, comprising:

a substrate;

a thin film transistor layer located on the substrate, and the thin film transistor layer comprising a plurality of thin film transistors separately located;

a planarization layer located on the thin film transistor layer, and a plurality of through holes located in the planarization layer respectively and correspondingly above the plurality of thin film transistors;

a plurality of anodes separately located on the planarization layer, and the plurality of anodes being coupled to the plurality of thin film transistors respectively through the plurality of through holes;

a pixel definition layer located on the planarization layer, and the pixel definition layer comprising a plurality of aperture areas which respectively correspond to the plurality of anodes and non aperture areas among the plurality of aperture areas;

a plurality of OLED light emitting layers respectively located on the plurality of anodes in the plurality of aperture areas of the pixel definition layer;

a cathode located on the plurality of OLED light emitting layers and the pixel definition layer, and the cathode comprising a first metal layer covering the plurality of OLED light emitting layers and the pixel definition layer with an entire surface, and a second metal layer corresponding to the non aperture areas of the pixel definition layer on the first metal layer, and the first metal layer appearing to be semi transparent, and an overlapping area of the first metal layer and the second metal appearing to be opaque.

A material of the first metal layer is magnesium silver alloy; a material of the second metal layer comprises at least one of magnesium, silver and aluminum.

A thickness of the first metal layer is 100 μm-200 μm; a thickness of the second metal layer is more than 100 μm.

The OLED display panel of the present invention further comprises a package layer located on the cathode, and a circular polarizer located on the package layer.

The package layer is a thin film package layer, and the package layer comprises a plurality of inorganic layers and organic layers stacked up and alternately located.

The present invention further provides an OLED display panel, comprising:

a substrate;

a thin film transistor layer located on the substrate, and the thin film transistor layer comprising a plurality of thin film transistors separately located;

a planarization layer located on the thin film transistor layer, and a plurality of through holes located in the planarization layer respectively and correspondingly above the plurality of thin film transistors;

a plurality of anodes separately located on the planarization layer, and the plurality of anodes being coupled to the plurality of thin film transistors respectively through the plurality of through holes;

a pixel definition layer located on the planarization layer, and the pixel definition layer comprising a plurality of aperture areas which respectively correspond to the plurality of anodes and non aperture areas among the plurality of aperture areas;

a plurality of OLED light emitting layers respectively located on the plurality of anodes in the plurality of aperture areas of the pixel definition layer;

a cathode located on the plurality of OLED light emitting layers and the pixel definition layer, and the cathode comprising a first metal layer covering the plurality of OLED light emitting layers and the pixel definition layer, and a second metal layer corresponding to the non aperture areas of the pixel definition layer on the first metal layer, and the first metal layer appearing to be semi transparent, and an overlapping area of the first metal layer and the second metal appearing to be opaque;

wherein a material of the first metal layer is magnesium silver alloy; a material of the second metal layer comprises at least one of magnesium, silver and aluminum;

wherein a thickness of the first metal layer is 100 μm-200 μm; a thickness of the second metal layer is more than 100 μm.

The benefits of the present invention are: in the manufacture method of the OLED provided by the present invention, the cathode of the made OLED display panel has a double layer structure. The cathode comprises a first metal layer of the entire surface and a second metal layer being located on the first metal layer and corresponding to the non pixel areas of the OLED display panel. Thus, in the pixel area of the OLED display panel, the cathode is constructed by the first metal layer and appears to be semi transparent. In the non pixel area of the OLED display panel, the cathode is constructed by stacking up the first metal layer, the second metal layer and appears to be opaque. Then, in one aspect, the transmission rate of the pixel area of the OLED display panel is not influenced, and meanwhile, no light outgoes from the non pixel area of the OLED display panel to effectively raise the contrast of the OLED display panel to promote the display result; in another aspect, by arranging the cathode to be a double layer structure, it can raise the conduction property of the cathode to decrease the power consumption of the OLED display panel. The present invention provides an OLED display panel. By arranging the cathode to be a double layer structure, on one hand, it can effectively raise the contrast of the OLED display panel to promote the display result, and on the other hand, it can raise the conduction property of the cathode to decrease the power consumption of the OLED display panel.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram that the light emitted by an OLED element in an OLED display panel according to prior art passes through and is reflected by the reflection electrode of a thin film transistor, and then outgoes from the non pixel area of the OLED display panel;

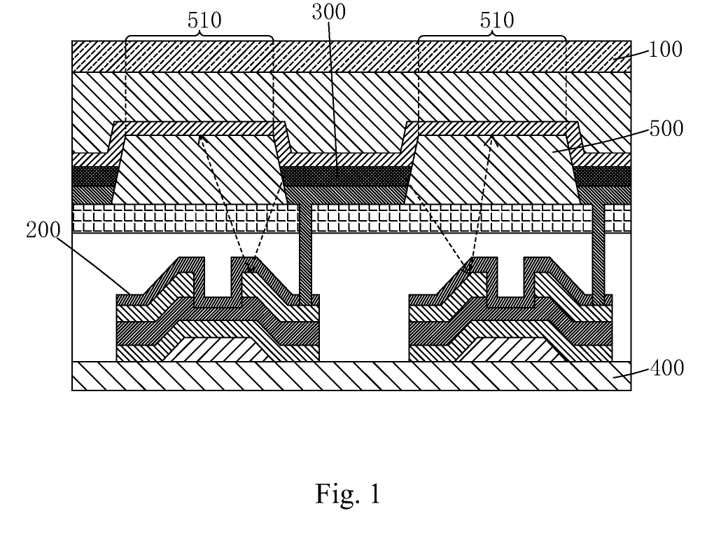

FIG. 2 is a flowchart of a manufacture method of an OLED display panel according to the present invention;

FIG. 3 is a diagram of step 1 of a manufacture method of an OLED display panel according to the present invention;

FIG. 4 is a diagram of step 2 of a manufacture method of an OLED display panel according to the present invention;

FIG. 5 is a diagram of step 3 of a manufacture method of an OLED display panel according to the present invention;

FIG. 6 is a diagram of step 4 of a manufacture method of an OLED display panel according to the present invention;

FIG. 7 is a diagram of step 5 of a manufacture method of an OLED display panel according to the present invention;

FIG. 8 is a diagram of step 6 of a manufacture method of an OLED display panel according to the present invention;

FIG. 9 is a diagram of step 7 of a manufacture method of an OLED display panel according to the present invention;

FIG. 10 is a diagram of step 8 of a manufacture method of an OLED display panel according to the present invention and a structure diagram of an OLED display panel according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

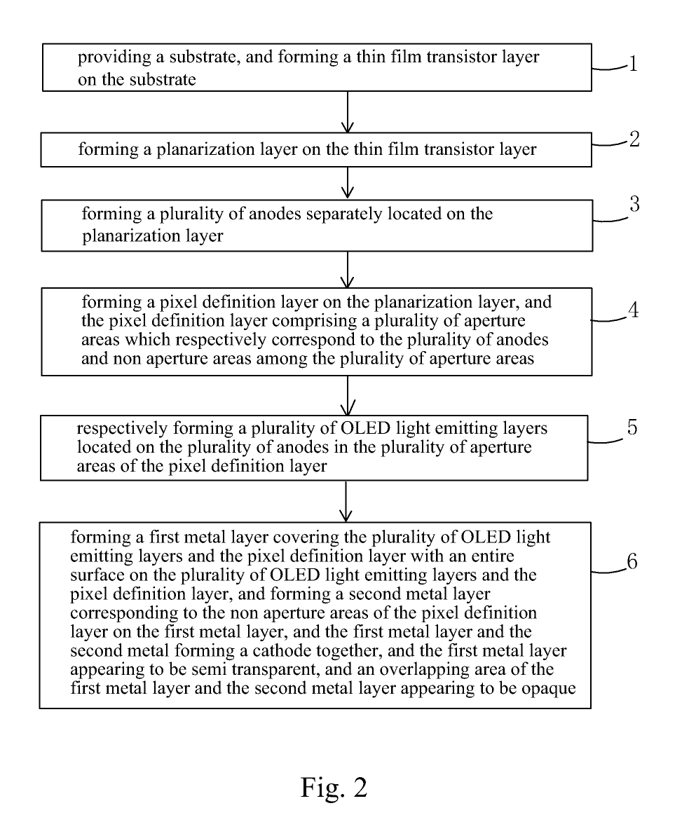

Please refer to FIG. 2. The present invention provides a manufacture method of an OLED display panel, comprising steps of:

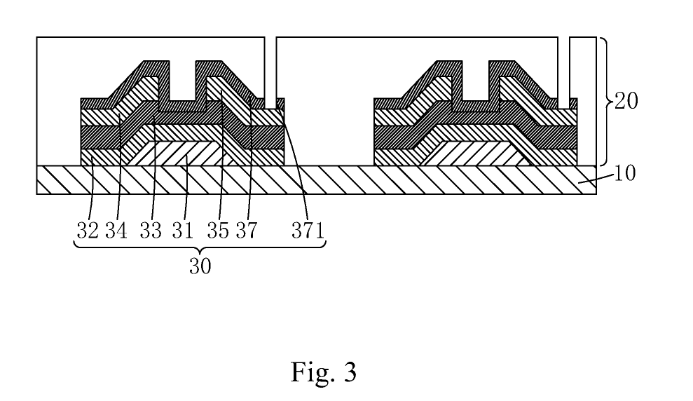

as shown in FIG. 3, providing a substrate 10, and forming a thin film transistor layer 20 on the substrate 10, and the thin film transistor layer 20 comprising a plurality of thin film transistors 30 separately located.

Specifically, the substrate 10 can be a rigid substrate or a flexible substrate. The rigid substrate is preferably to be a glass substrate, and the flexible substrate is preferably to be a polyimide layer.

As the substrate 10 is a rigid substrate, the OLED display panel manufactured thereafter according to the present invention is a rigid OLED display panel. As the substrate 10 is a flexible substrate, the OLED display panel manufactured thereafter according to the present invention is a flexible OLED display panel.

Specifically, as shown in FIG. 3, the thin film transistor 30 comprises a gate 31 located on the substrate 10, a gate insulation layer 32 located on the gate 31, a semiconductor layer 33 located on the gate insulation layer 32, a source 34 and a drain 35 located on the semiconductor layer 33 and a passivation layer 37 located on the source 34, the drain 35 and the semiconductor layer 33; the passivation layer 37 comprises vias 371 correspondingly above the drains 35.

The reflection electrode in the thin film transistor 30 comprises structure layers manufactured with metal materials, a gate 31, a source 34 and a drain 35.

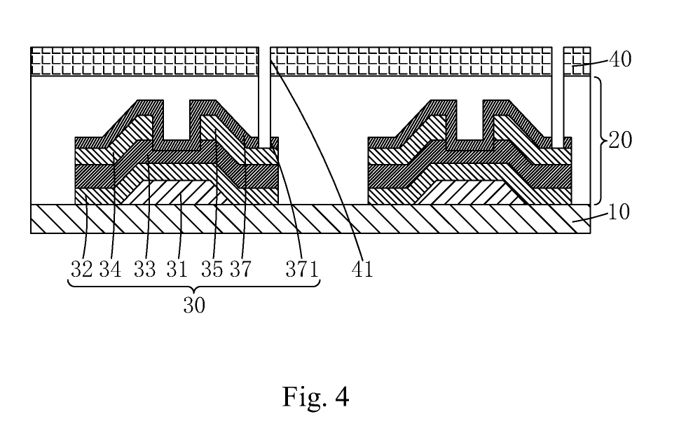

As shown in FIG. 4, forming a planarization layer 40 on the thin film transistor layer 20, and forming a plurality of through holes 41 in the planarization layer 40 respectively and correspondingly above the plurality of thin film transistors 30.

Specifically, the planarization layer 40 is an organic material.

Specifically, as shown in FIG. 4, the through holes 41 in the planarization layer 40 correspond to the vias 371 in the passivation layer 37.

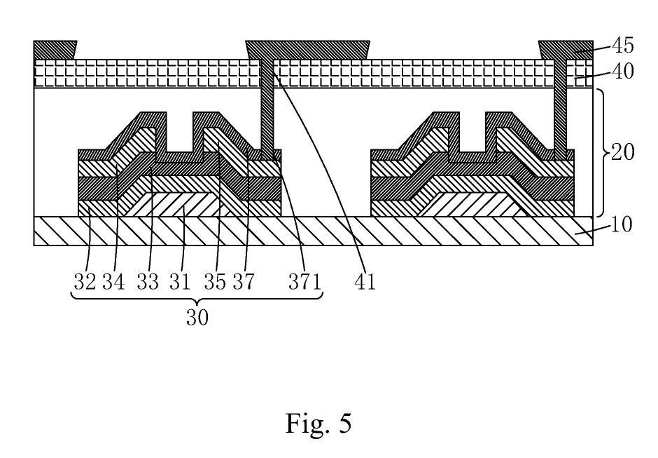

As shown in FIG. 5, forming a plurality of anodes 45 separately located on the planarization layer 40, and the plurality of anodes 45 being coupled to the plurality of thin film transistors 30 respectively through the plurality of through holes 41.

Specifically, the anode 45 is a reflection electrode so that the OLED display panel of the present invention constructs a top light emitting OLED display panel.

Preferably, the anode 45 comprises two Indium Tin Oxide (ITO) layers and a silver (Ag) layer sandwiched between the two Indium Tin Oxide layers.

Specifically, as shown in FIG. 5, the anodes 45 are respectively coupled to the drains 35 of the plurality of thin film transistors 30 through the plurality of through holes 41 in the planarization layer 40 and the plurality of vias 371 in the passivation layer.

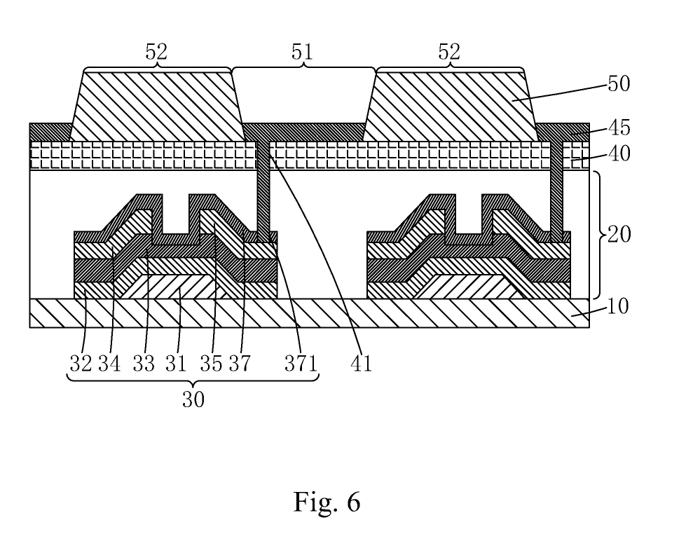

As shown in FIG. 6, forming a pixel definition layer 50 on the planarization layer 40, and the pixel definition layer 50 comprising a plurality of aperture areas 51 which respectively correspond to the plurality of anodes 45 and non aperture areas 52 among the plurality of aperture areas 51.

Specifically, the aperture areas 51 and the non aperture areas 52 of the pixel definition layer 50 respectively correspond to the pixel areas and the non pixel areas of the OLED display panel.

Specifically, the pixel definition layer 50 is transparent organic material.

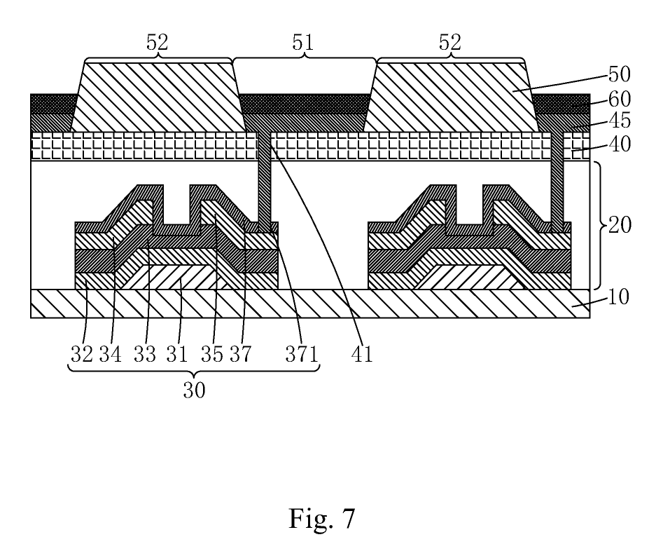

As shown in FIG. 7, respectively forming a plurality of OLED light emitting layers 60 located on the plurality of anodes 45 in the plurality of aperture areas 51 of the pixel definition layer 50.

Specifically, the evaporation method is employed to form the plurality of OLED light emitting layers 60.

Specifically, the OLED light emitting layers 60 comprises a Hole Injection Layer (not shown), a Hole Transporting Layer (not shown), a light emitting layer (not shown), an Electron Transport Layer (not shown) and an Electron Injection Layer (not shown) stacking up on the anode 45 from bottom to top in order.

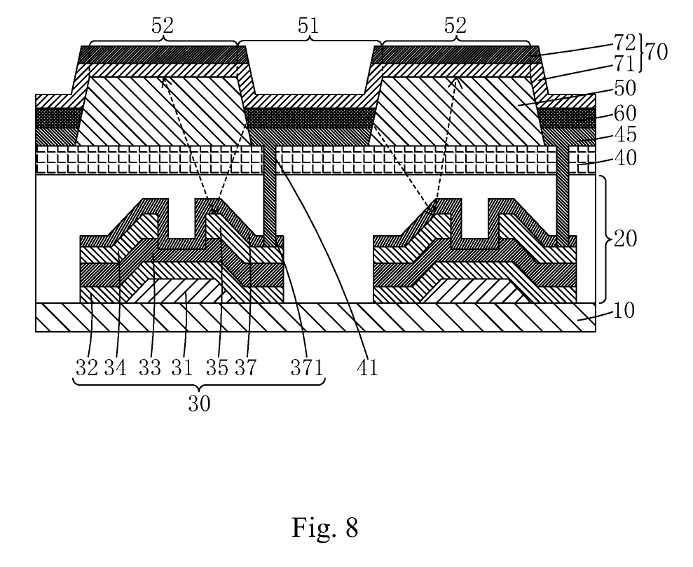

As shown in FIG. 8, forming a first metal layer 71 covering the plurality of OLED light emitting layers 60 and the pixel definition layer 50 with an entire surface on the plurality of OLED light emitting layers 60 and the pixel definition layer 50, and forming a second metal layer 72 corresponding to the non aperture areas 52 of the pixel definition layer 50 on the first metal layer 71, and the first metal layer 71 and the second metal 72 forming a cathode 70 together, and the first metal layer 71 appearing to be semi transparent, and an overlapping area of the first metal layer 71 and the second metal layer 72 appearing to be opaque.

Specifically, a material of the first metal layer 71 is magnesium silver alloy.

Specifically, a material of the second metal layer 72 comprises at least one of magnesium, silver and aluminum of which the conduction property of the metal material is better.

Specifically, an evaporation process is employed to form the first metal layer 71 and the second metal layer 72.

Specifically, the evaporation process of the first metal layer 71 uses the normal metal mask. The evaporation process of the second metal layer 72 uses the FMM (fine metal mask).

Specifically, a thickness of the first metal layer 71 is 100 μm-200 μm, and the thickness range can ensure that the first metal layer 71 appears to be semi transparent.

Specifically, a thickness of the second metal layer 72 is more than 100 μm. The larger the thickness of the second metal layer 72 is, the better the conduction property of the anode 70 becomes.

In the OLED display panel according to prior art, the cathode of the top light emitting OLED element is generally constructed with the first metal layer which appears to be semi transparent. The present invention adds a second metal layer 72 on the first metal layer 71. In one aspect, it can ensure that the part of the cathode 70 correspondingly above the OLED light emitting layer 60 is constructed only by the first metal layer 71 which appears to be semi transparent to ensure that the outgoing light of the OLED light emitting layer 60 will not be influenced, and meanwhile it can prevent that the light emitted by the OLED light emitting layer 60 is reflected by the reflection electrode of the thin film transistor 30, and then enters the human eyes through the non aperture area 52 (non pixel area) of the pixel definition layer 50 to raise the contrast of the OLED display panel; in another aspect, by adding the second metal layer 72 on the first metal layer 71, the thickness of the cathode 70 also can be increased to reduce the resistance of the cathode 70 to promote the conduction property of the cathode 70 for decreasing the power consumption of the OLED display panel.

The foregoing step 1 to step 6 accomplish the main manufacture steps of the OLED display panel. In the normal condition, for promoting the usage lifetime and the display result of the OLED element, it is also required to package the OLED element and to adhere the circular polarizer on the packager layer. Thus, the manufacture method of the OLED display panel according to the present invention further comprises:

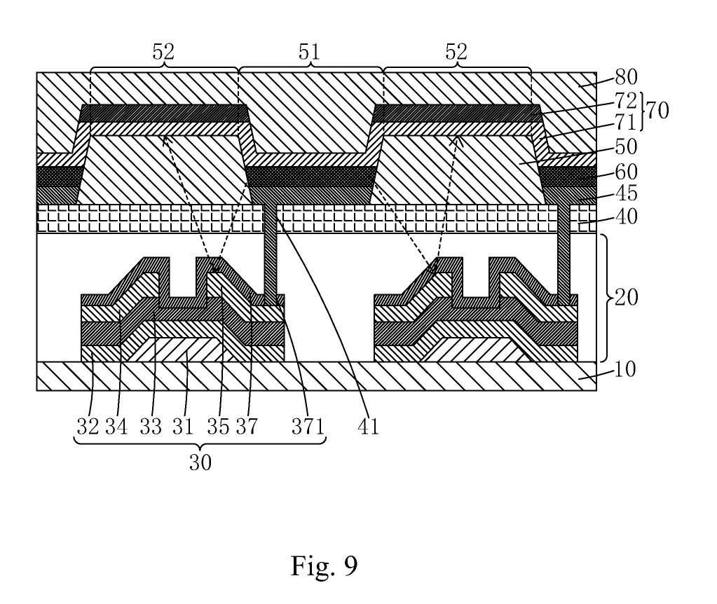

As shown in FIG. 9, forming a package layer 80 on the cathode 70 to stop the corrosion of the external water and oxygen to the OLED element to promote the usage life time of the OLED element.

Specifically, the package layer 80 can be a glass package layer or a thin film package (TFE, Thin Film Encapsulation) layer, and preferably a thin film package layer.

Specifically, the thin film package layer comprises a plurality of inorganic layers and organic layers stacked up and alternately located; the material of the inorganic layers comprises at least one of silicon oxide (SiOx), silicon nitride (SiNx) and silicon oxynitride (SiOxNx); the material of the organic layers comprises one or more of acrylic, HMDSO, polyhydroxy acrylics, polycarbonate and polystyrene.

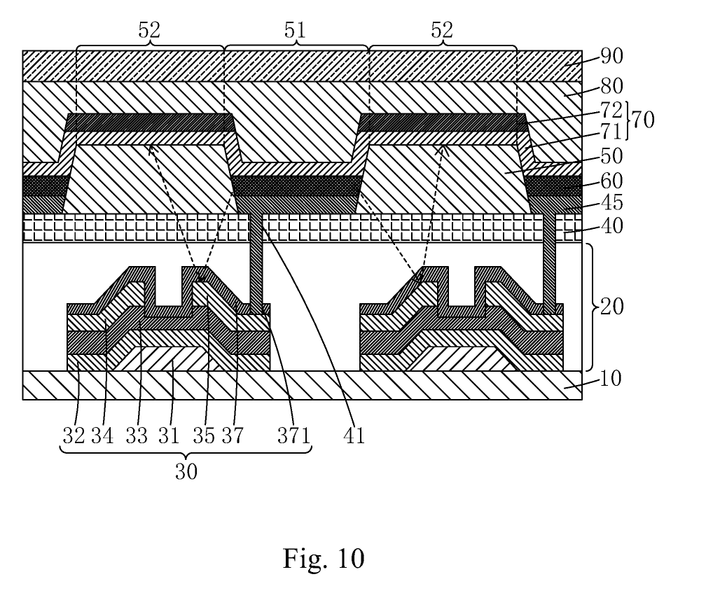

As shown in FIG. 10, adhering a circular polarizer 90 on the package layer 80 to prevent the influence of the external light to the contrast of the OLE D display panel and to promote the display result of the OLED display panel.

In the aforesaid manufacture method of the OLED display panel, the made cathode 70 has a double layer structure. The cathode 70 comprises a first metal layer 71 of the entire surface and a second metal layer 72 being located on the first metal layer 71 and corresponding to the non pixel areas of the OLED display panel. Thus, in the pixel area of the OLED display panel, the cathode 70 is constructed by the first metal layer 71 and appears to be semi transparent. In the non pixel area of the OLED display panel, the cathode 70 is constructed by stacking up the first metal layer 71, the second metal layer 72 and appears to be opaque. Then, in one aspect, the transmission rate of the pixel area of the OLED display panel is not influenced, and meanwhile, no light outgoes from the non pixel area of the OLED display panel to effectively raise the contrast of the OLED display panel to promote the display result; in another aspect, by arranging the cathode 70 to be a double layer structure, it can raise the conduction property of the cathode 70 to decrease the power consumption of the OLED display panel.

Please refer to FIG. 10. Based on the aforesaid manufacture method of the OLED display panel, the present invention further provides an OLED display panel, comprising:

a substrate 10;

a thin film transistor layer 20 located on the substrate 10, and the thin film transistor layer 20 comprising a plurality of thin film transistors 30 separately located;

a planarization layer 40 located on the thin film transistor layer 20, and a plurality of through holes 41 located in the planarization layer 40 respectively and correspondingly above the plurality of thin film transistors 30;

a plurality of anodes 45 separately located on the planarization layer 40, and the plurality of anodes 45 being coupled to the plurality of thin film transistors 30 respectively through the plurality of through holes 41;

a pixel definition layer 50 located on the planarization layer 40, and the pixel definition layer 50 comprising a plurality of aperture areas 51 which respectively correspond to the plurality of anodes 45 and non aperture areas 52 among the plurality of aperture areas 51;

a plurality of OLED light emitting layers 60 respectively located on the plurality of anodes 45 in the plurality of aperture areas 51 of the pixel definition layer 50;

a cathode 70 located on the plurality of OLED light emitting layers 60 and the pixel definition layer 50, and the cathode 70 comprising a first metal layer 71 covering the plurality of OLED light emitting layers 60 and the pixel definition layer 50 with an entire surface, and a second metal layer 72 corresponding to the non aperture areas 52 of the pixel definition layer 50 on the first metal layer 71, and the first metal layer 71 appearing to be semi transparent, and an overlapping area of the first metal layer 71 and the second metal layer 72 appearing to be opaque.

Specifically, the substrate 10 can be a rigid substrate or a flexible substrate. The rigid substrate is preferably to be a glass substrate, and the flexible substrate is preferably to be a polyimide layer.

Specifically, the thin film transistor 30 comprises a gate 31 located on the substrate 10, a gate insulation layer 32 located on the gate 31, a semiconductor layer 33 located on the gate insulation layer 32, a source 34 and a drain 35 located on the semiconductor layer 33 and a passivation layer 37 located on the source 34, the drain 35 and the semiconductor layer 33; the passivation layer 37 comprises vias 371 correspondingly above the drains 35 and corresponding to the through holes 41 and the anodes 45 are respectively coupled to the drains 35 of the plurality of thin film transistors 30 through the plurality of through holes 41 and the vias 371.

Specifically, the planarization layer 40 is an organic material.

Specifically, the anode 45 is a reflection electrode so that the OLED display panel of the present invention constructs a top light emitting OLED display panel.

Preferably, the anode 45 comprises two Indium Tin Oxide (ITO) layers and a silver (Ag) layer sandwiched between the two Indium Tin Oxide layers.

Specifically, the pixel definition layer 50 is transparent organic material.

Specifically, the OLED light emitting layers 60 comprises a Hole Injection Layer (not shown), a Hole Transporting Layer (not shown), a light emitting layer (not shown), an Electron Transport Layer (not shown) and an Electron Injection Layer (not shown) stacking up on the anode 45 from bottom to top in order.

Specifically, a material of the first metal layer 71 is magnesium silver alloy.

Specifically, a material of the second metal layer 72 comprises at least one of magnesium, silver and aluminum of which the conduction property of the metal material is better.

Specifically, a thickness of the first metal layer 71 is 100 μm-200 μm, and a thickness of the second metal layer 72 is more than 100 μm.

The OLED display panel of the present invention further comprises a package layer 80 located on the cathode 70, and a circular polarizer 90 located on the package layer 80.

Specifically, the package layer 80 can be a glass package layer or a thin film package layer, and preferably a thin film package layer.

Specifically, the thin film package layer comprises a plurality of inorganic layers and organic layers stacked up and alternately located; the material of the inorganic layers comprises at least one of silicon oxide (SiOx), silicon nitride (SiNx) and silicon oxynitride (SiOxNx); the material of the organic layers comprises one or more of acrylic, HMDSO, polyhydroxy acrylics, polycarbonate and polystyrene.

In the aforesaid OLED display panel, by arranging the cathode 70 to be a double layer structure, on one hand, it can effectively raise the contrast of the OLED display panel to promote the display result, and on the other hand, it can raise the conduction property of the cathode 70 to decrease the power consumption of the OLED display panel.

In conclusion, the present invention provides an OLED display panel and a manufacture method thereof. In the manufacture method of the OLED display panel according to the present invention, the cathode of the made OLED display panel has a double layer structure. The cathode comprises a first metal layer of the entire surface and a second metal layer being located on the first metal layer and corresponding to the non pixel areas of the OLED display panel. Thus, in the pixel area of the OLED display panel, the cathode is constructed by the first metal layer and appears to be semi transparent. In the non pixel area of the OLED display panel, the cathode is constructed by stacking up the first metal layer, the second metal layer and appears to be opaque. Then, in one aspect, the transmission rate of the pixel area of the OLED display panel is not influenced, and meanwhile, no light outgoes from the non pixel area of the OLED display panel to effectively raise the contrast of the OLED display panel to promote the display result; in another aspect, by arranging the cathode to be a double layer structure, it can raise the conduction property of the cathode to decrease the power consumption of the OLED display panel. In the OLED display panel of the present invention, by arranging the cathode to be a double layer structure, on one hand, it can effectively raise the contrast of the OLED display panel to promote the display result, and on the other hand, it can raise the conduction property of the cathode to decrease the power consumption of the OLED display panel.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of an OLED display panel, comprising steps of:
providing a substrate, and forming a thin film transistor layer on the substrate, and the thin film transistor layer comprising a plurality of thin film transistors separately located;
forming a planarization layer on the thin film transistor layer, and forming a plurality of through holes in the planarization layer respectively and correspondingly above the plurality of thin film transistors;
forming a plurality of anodes separately located on the planarization layer, and the plurality of anodes being coupled to the plurality of thin film transistors respectively through the plurality of through holes;
forming a pixel definition layer on the planarization layer, and the pixel definition layer comprising a plurality of aperture areas which respectively correspond to the plurality of anodes and non aperture areas among the plurality of aperture areas;
respectively forming a plurality of OLED light emitting layers located on the plurality of anodes in the plurality of aperture areas of the pixel definition layer;
forming a first metal layer covering the plurality of OLED light emitting layers and the pixel definition layer with an entire surface on the plurality of OLED light emitting layers and the pixel definition layer, and forming a second metal layer corresponding to the non aperture areas of the pixel definition layer on the first metal layer, and the first metal layer and the second metal forming a cathode together, and the first metal layer appearing to be semi transparent, and an overlapping area of the first metal layer and the second metal layer appearing to be opaque.

2. The manufacture method of the OLED display panel according to claim 1, wherein an evaporation process is employed to form the first metal layer and the second metal layer; a material of the first metal layer is magnesium silver alloy; a material of the second metal layer comprises at least one of magnesium, silver and aluminum.

3. The manufacture method of the OLED display panel according to claim 1, wherein a thickness of the first metal layer is 100 μm-200 μm; a thickness of the second metal layer is more than 100 μm.

4. The manufacture method of the OLED display panel according to claim 1, further comprising:
forming a package layer on the cathode;
adhering a circular polarizer on the package layer.

5. The manufacture method of the OLED display panel according to claim 4, wherein the package layer is a thin film package layer, and the package layer comprises a plurality of inorganic layers and organic layers stacked up and alternately located.

6. An OLED display panel, comprising:
a substrate;
a thin film transistor layer located on the substrate, and the thin film transistor layer comprising a plurality of thin film transistors separately located;
a planarization layer located on the thin film transistor layer, and a plurality of through holes located in the planarization layer respectively and correspondingly above the plurality of thin film transistors;
a plurality of anodes separately located on the planarization layer, and the plurality of anodes being coupled to the plurality of thin film transistors respectively through the plurality of through holes;
a pixel definition layer located on the planarization layer, and the pixel definition layer comprising a plurality of aperture areas which respectively correspond to the plurality of anodes and non aperture areas among the plurality of aperture areas;
a plurality of OLED light emitting layers respectively located on the plurality of anodes in the plurality of aperture areas of the pixel definition layer;
a cathode located on the plurality of OLED light emitting layers and the pixel definition layer, and the cathode comprising a first metal layer covering the plurality of OLED light emitting layers and the pixel definition layer with an entire surface, and a second metal layer corresponding to the non aperture areas of the pixel definition layer on the first metal layer, and the first metal layer appearing to be semi transparent, and an overlapping area of the first metal layer and the second metal appearing to be opaque.

7. The OLED display panel according to claim 6, wherein a material of the first metal layer is magnesium silver alloy; a material of the second metal layer comprises at least one of magnesium, silver and aluminum.

8. The OLED display panel according to claim 6, wherein a thickness of the first metal layer is 100 μm-200 μm; a thickness of the second metal layer is more than 100 μm.

9. The OLED display panel according to claim 6, further comprising a package layer located on the cathode, and a circular polarizer located on the package layer.

10. The OLED display panel according to claim 9, wherein the package layer is a thin film package layer, and the package layer comprises a plurality of inorganic layers and organic layers stacked up and alternately located.

11. An OLED display panel, comprising:
a substrate;
a thin film transistor layer located on the substrate, and the thin film transistor layer comprising a plurality of thin film transistors separately located;
a planarization layer located on the thin film transistor layer, and a plurality of through holes located in the planarization layer respectively and correspondingly above the plurality of thin film transistors;
a plurality of anodes separately located on the planarization layer, and the plurality of anodes being coupled to the plurality of thin film transistors respectively through the plurality of through holes;
a pixel definition layer located on the planarization layer, and the pixel definition layer comprising a plurality of aperture areas which respectively correspond to the plurality of anodes and non aperture areas among the plurality of aperture areas;
a plurality of OLED light emitting layers respectively located on the plurality of anodes in the plurality of aperture areas of the pixel definition layer;
a cathode located on the plurality of OLED light emitting layers and the pixel definition layer, and the cathode comprising a first metal layer covering the plurality of OLED light emitting layers and the pixel definition layer, and a second metal layer corresponding to the non aperture areas of the pixel definition layer on the first metal layer, and the first metal layer appearing to be semi transparent, and an overlapping area of the first metal layer and the second metal appearing to be opaque;
wherein a material of the first metal layer is magnesium silver alloy; a material of the second metal layer comprises at least one of magnesium, silver and aluminum;
wherein a thickness of the first metal layer is 100 μm-200 μm; a thickness of the second metal layer is more than 100 μm.

12. The OLED display panel according to claim 11, further comprising a package layer located on the cathode, and a circular polarizer located on the package layer.

13. The OLED display panel according to claim 12, wherein the package layer is a thin film package layer, and the package layer comprises a plurality of inorganic layers and organic layers stacked up and alternately located.
